(19) United States
(12) Patent Application Publication
(10) Pub. No.: US 2014/0138844 A1
(43) Pub. Date: May 22, 2014

(54) PATTERNED BACKSIDE METAL GROUND PLANE FOR IMPROVED METAL ADHESION

(71) Applicant: INTERNATIONAL BUSINESS MACHINES CORPORATION, Armonk, NY (US)

(72) Inventors: Jeffrey P. Gambino, Westford, VT (US); Kenneth F. McAvey, JR., Winooski, VT (US); Charles F. Musante, South Burlington, VT (US); Anthony K. Stamper, Williston, VT (US)

(73) Assignee: INTERNATIONAL BUSINESS MACHINES CORPORATION, Armonk, NY (US)

(21) Appl. No.: 13/683,050

(22) Filed: Nov. 21, 2012

(51) Int. Cl. H01L 23/52; H01L 21/50

(52) U.S. Cl. CPC H01L 23/52; H01L 21/50
USPC 257/774; 438/106; 438/113

(57) ABSTRACT

A patterned backside metal ground plane for improved metal adhesion and methods of manufacture are disclosed herein. The method includes forming at least one die on a substrate. The at least one die is formed adjacent to a dicing channel and includes through silicon vias (TSVs). The method further includes forming a metalized ground plane on a backside of the substrate in contact with the TSVs and which is located in such areas on the backside of the substrate that it does not interfere with dicing operations performed within the dicing channel.

### FIELD OF THE INVENTION

The invention relates to semiconductor structures and, more particularly, to patterned backside metal ground planes for improved metal adhesion and methods of manufacture.

### BACKGROUND

Packaging lead inductance is a major design issue, particularly for RF analog chips such as WLAN power amplifiers (PA). For example, the emitter ground leads used in SiGe heterojunction bipolar transistor (HBT) RF designs are normally contacted to the package either using multiple wire bonds or flip chip solder bumps. Wire bond package ground leads have high inductance, on the order of 160 pH, which results in unacceptable PA insertion loss. Although flip chip solder bumps have low inductance, they increase packaging complexity and are expensive.

Accordingly, there exists a need in the art to overcome the deficiencies and limitations described hereinabove.

### SUMMARY

In an aspect of the invention, a method comprises forming at least one die on a substrate. The at least one die is formed adjacent to a dicing channel and comprises through silicon vias (TSVs). The method further comprises forming a metalized ground plane on a backside of the substrate in contact with the TSVs and which is located in such areas on the backside of the substrate that it does not interfere with dicing operations performed within the dicing channel.

In an aspect of the invention, a method comprises forming a plurality of dies on a substrate separated by dicing channels. The plurality of dies each comprise a plurality of through silicon vias (TSVs). The method further comprises depositing a metal on selected areas on a backside of the substrate such that the metal is patterned to contact the TSVs on the plurality of dies. The method further comprises dicing the substrate to form the plurality of dies, wherein the dicing will avoid contact with the metal on the selected areas on the backside of the substrate.

In an aspect of the invention, a structure comprises a substrate comprising a plurality of dies, each having a plurality of through silicon vias. The structure further comprises dicing channels provided between the plurality of dies, and a metalized ground plane on a backside of the plurality of the dies in contact with the silicon vias. The dicing channels are substantially devoid of the metalized ground plane.

In another aspect of the invention, a design structure tangibly embodied in a machine readable storage medium for designing, manufacturing, or testing an integrated circuit is provided. The design structure comprises the structures of the present invention. In further embodiments, a hardware description language (HDL) design structure encoded on a machine-readable data storage medium comprises elements that when processed in a computer-aided design system generates a machine-executable representation of the patterned backside metal ground planes, which comprises the structures of the present invention. In still further embodiments, a method in a computer-aided design system is provided for generating a functional design model of the patterned backside metal ground planes. The method comprises generating a functional representation of the structural elements of the patterned backside metal ground planes.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIG. 1 shows a backside of a plurality of dies on a substrate in accordance with aspects of the present invention;

FIG. 2 shows a patterned backside metal and methods of manufacture in accordance with aspects of the present invention;

FIG. 3 shows a patterned backside metal with metal pads and methods of manufacture in accordance with additional aspects of the present invention;

FIG. 4 shows a patterned backside metal and methods of manufacture in accordance with additional aspects of the present invention;

FIG. 5 shows a packaged module with a backside metal ground plane attached to a substrate in accordance with aspects of the present invention; and

FIG. 6 is a flow diagram of a design process used in semiconductor design, manufacture, and/or test.

### DETAILED DESCRIPTION

The invention relates to semiconductor structures and, more particularly, to patterned backside metal ground planes for improved metal adhesion and methods of manufacture. More specifically, the present invention relates to structures and methods of forming backside metal in specific locations (i.e., patterned backside metal) on a backside surface of a substrate. In embodiments, the metal is not formed in any dicing channel; instead, the backside metal is formed only on the die, and preferably in limited regions of the backside of the die, which contact through-silicon vias. In embodiments, the backside metal is patterned differently than wiring; that is, the backside metal is patterned to form patches and/or islands of metal which are all coupled to the same potential (e.g., ground).

Grounded through silicon vias (TSVs) can be used to reduce ground lead inductance and reduce the bond pad area on the chip surface. In such implementations, a metal is blanket deposited on the backside of the substrate, including in the dicing channel, to act as a ground plane. However, in such implementations, problems with metal adhesion are commonly observed during dicing. That is, the dicing process introduces a large peeling stress at the metal-Si interface, which can cause the metal to peel from the corners and edges of the die. Often, the peeled metal “folds over”, resulting in a very non-planar surface on the back of the die, which can cause problems with die yield and reliability.

Advantageously, the present invention solves the metal peeling problem by using a patterned backside metal ground plane, which, in some embodiments, is not deposited in the dicing channel. This allows the wafer to be diced without affecting the backside metal, thereby forming dies with a planar backside metal ground plane. The patterned backside metal ground plane can be formed with minimal additional cost by using a shadow mask, for example, during metal deposition. Other options for metal patterning contemplated by the present invention include, for example, liftoff of the metal and subtractive etching of the metal. By using a patterned backside metal ground plane, a less expensive dicing process can be used, thereby reducing the overall cost of the packaged module. Also, in embodiments, the use of the backside metal will reduce ground lead inductance and chip area that ordinarily occurs with wirebonding substrate designs.

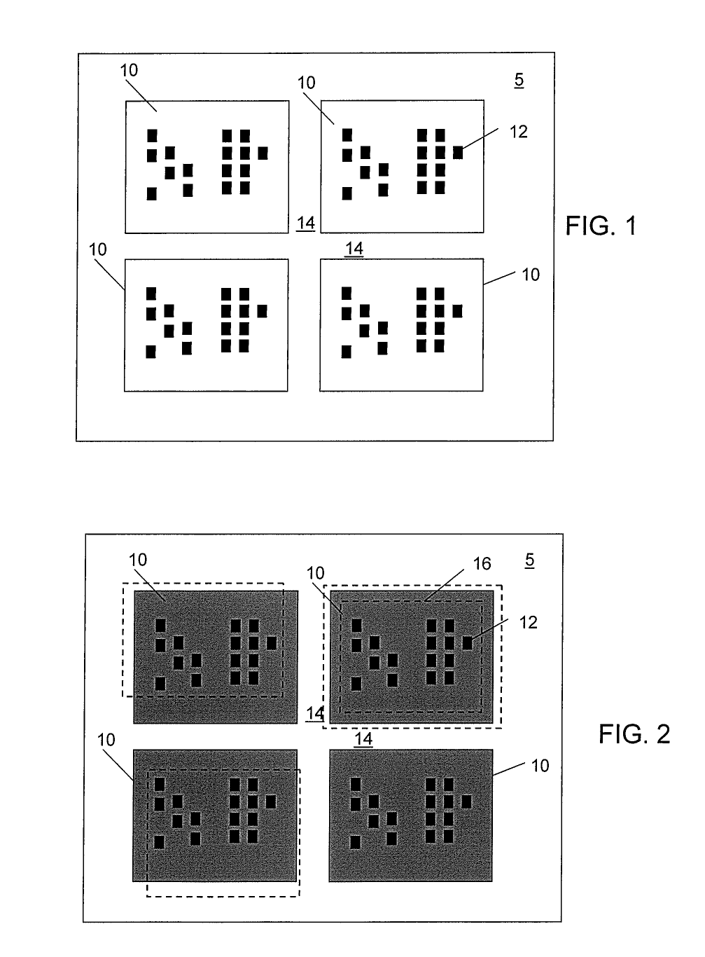

FIG. 1 shows a backside of a plurality of dies on a wafer in accordance with aspects of the present invention. More specifically, FIG. 1 shows four dies 10, each with a plurality of through silicon vias 12. It should be understood by those of ordinary skill in the art that FIG. 1 should not be limited to only four dies 10, as any amount of dies on a wafer or substrate 5 (hereinafter generally referred to as the substrate) are contemplated by the present invention. Also, it should be understood by those of ordinary skill in the art that each die 10 is representative of a small block of semiconductor material, on which a given functional circuit is fabricated. The dies 10 are each separated by a dicing channel 14, which is used to dice the substrate 5 into separate dies 10. The dicing can be performed by a mechanical cutting or a laser process, for example.

In embodiments, the through silicon vias (TSV)12 can be formed using conventional processes, such as, for example, lithography, etching and deposition processes, with a backside polishing and grinding process, all of which are schematically represented in FIGS. 1-4. The TSVs 12 are formed through the substrate 5.

As one example, Bosch deep reactive ion etching (DRIE) can be used to fabricate the TSVs with almost any diameter, from the submicrometer level to hundreds of micrometers. In more specific embodiments, a via can be formed in a front side of the die 10 using conventional lithography and etching processes. The via would typically extend only partially through the die 10 (or substrate 5). After formation of the via, metal can be deposited therein using conventional deposition processes such as, for example, electroplating or chemical vapor deposition techniques. In embodiments, the metal can be any appropriate metal used in semiconductor manufacturing processes for TSVs such as, for example, copper. The backside of the substrate 5 then undergoes a thinning process, e.g., a polishing and grinding process, in order to expose the TSVs 12.

FIG. 2 shows a patterned backside metal and methods of manufacture in accordance with aspects of the present invention. More specifically, as shown in FIG. 2, a backside metal 16 is formed on the backside of the die 10, in contact with the TSVs 12. In embodiments, the backside metal 16 is not formed in the dicing channel 14. In this way, peeling of the backside metal is avoided after the dicing process. Also, as should be understood by those of ordinary skill in the art, in each of the embodiments described herein, the backside metal 16 will act as a metalized ground plane, contacting the Si substrate and the metal TSVs 12. The substrate 5 is diced, and the die is attached to a ground plane on the package using a conductive epoxy.

In embodiments, the backside metal 16 can be formed by different processes, including, for example, the use of a shadow mask, a liftoff process or a subtractive etch process, all of which are schematically represented in FIGS. 2-4. In each of the embodiments, the backside metal 16 can be, for example, copper or gold, with a titanium diffusion layer. In embodiments, other metals are also contemplated by the present invention. The backside metal 16 can be deposited using, for example, a sputter deposition method; although other deposition processes are also contemplated by the present invention such as, for example, chemical vapor deposition. In any of the deposition processes, the backside metal 16 has a planar surface, which can be formed by the deposition process or through additional processing such as, for example, chemical mechanical polishing (CMP). In any of the above embodiments, the dies 10 are diced using a mechanical or laser cutting process.

In a shadow mask process, a mechanical stencil mask is placed over the wafer (i.e., between the wafer and the metal target), with openings in the mask where metal deposition is required on the wafer. The mechanical stencil mask blocks the deposition of metal in the dicing channel 14 during subsequent deposition processes. In embodiments, the shadow mask can be a thin layer of metal with openings as required for deposition on the die, but not on the dicing channel 14. After placement of the stencil mask, metal is deposited on the backside of the die 10 using conventional deposition methods such as, for example, a sputter deposition, evaporation, or chemical vapor deposition process. The deposition of the backside metal is blocked in the dicing channel 14 by the stencil mask.

In the liftoff process, a resist can be applied to the backside of the substrate, after grinding and polishing processes that expose the TSVs 12. The resist is formed in an inverse pattern, created from a sacrificial stencil layer (e.g., resist) which is deposited in the dicing channel 14 (on the surface of the substrate 5). This can be accomplished by forming openings through the resist layer (e.g., resist apply, expose, develop) so that target material (e.g., backside metal 16) can reach the surface of the substrate only in regions, e.g., on the die 12, in contact with the TSVs 12. The backside metal 16 is then deposited over the substrate 5, including on the dies 10. This deposition reaches the surface of the substrate 5 in the open regions and stays on the top of the sacrificial stencil layer (resist) in the regions where it was not previously opened, e.g., dicing channel 14. When the sacrificial layer is washed away, the metal material on the top of the resist is lifted-off and washed together with the resist. After the lift-off, the target material, e.g., backside metal 16, remains only in the regions where it had a direct contact with the substrate, e.g., on the dies 10.

In embodiments, the backside metal 16 may be overlapped or underlapped with the dies 10. For example, as shown in FIG. 2, it is contemplated by the present invention that the backside metal 16 can be formed partially in the dicing channel 14, as shown by the dashed lines within the dicing channel 14, to the extent that subsequent dicing processes can be performed without interference from the backside metal 16, e.g., dicing operation performed on the substrate 5 (to form the plurality of dies 10) will not affect the metal on the selected areas on a backside of the substrate 5. In this way, the backside metal 16 (e.g., metalized ground plane) on a backside of the plurality of the dies 10 will contact with the TSVs 12; whereas, the dicing channels 14 are substantially devoid of the backside metal 16 (e.g., metalized ground plane). The backside metal 16 can be completely contained, e.g., underlapped, within the die 10, also represented by the dashed lines.

In the subtractive etching process, a backside metal 16 is blanket deposited on the backside of the substrate 5, e.g., on the die 10 and within the dicing channel 14. As in any of the embodiments, the backside metal 16 can be copper or gold with a diffusion layer of titanium. In embodiments, the titanium will improve the adhesion of the copper or gold on the substrate. In embodiments, a resist is formed over the metal, which is then exposed and developed to form a pattern, e.g., openings over the dicing channel 14. The exposed metal is then removed using a wet etching process with a chemistry to remove the metal in the dicing channel 14. In this way, metal is only left on the die 10 or portions thereof. The resist is then stripped using oxygen ashing or organic solvents.

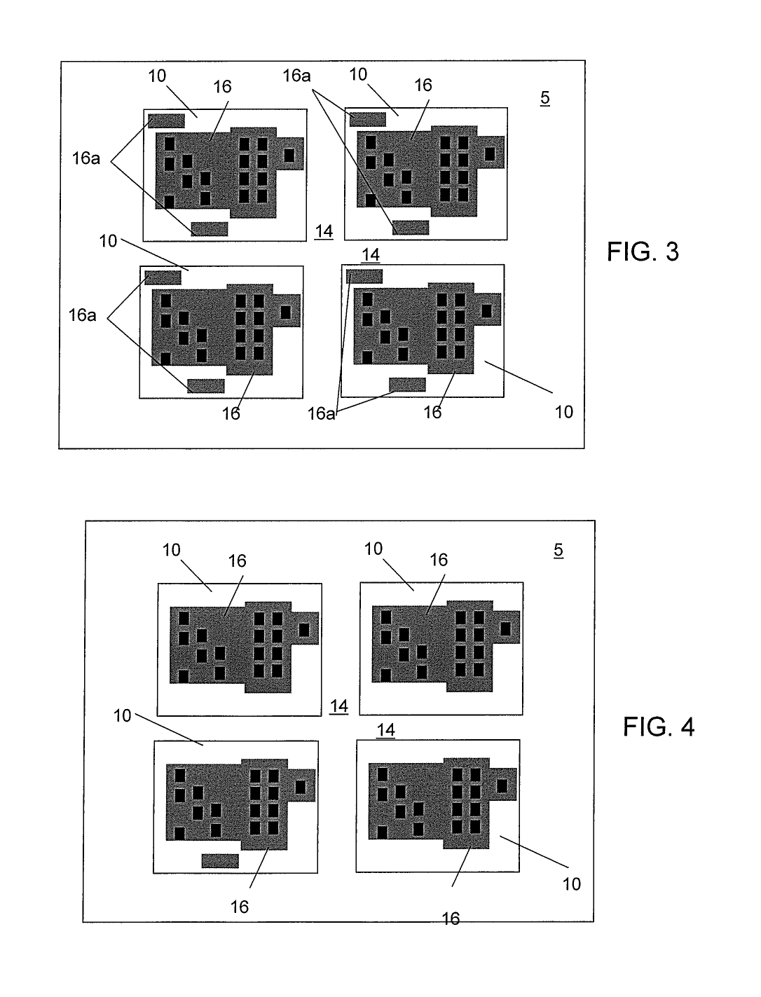

FIG. 3 shows a patterned backside metal and methods of manufacture in accordance with additional aspects of the present invention. In this embodiment, the backside metal 16 is provided in selected locations over the TSVs 12. That is, the backside metal 16 does not entirely cover the dies 10; instead, the backside metal 16 covers the TSVs 12.

In embodiments, the deposition of the metal will also form metal pads 16a. The metal pads 16a are provided at strategic locations on the dies 10 to provide mechanical support. In embodiments, the metal pads 16a can be dummy metal shapes formed for stability on the backside of the die 10. That is, the metal pads 16a can be formed and placed such that the die 10 will sit flatly on the package substrate, during packaging. The metal pad 16a and the backside metal 16 can be formed using a shadow mask, liftoff process or subtractive etch as described above. In any of the deposition processes, the backside metal 16 and the metal pads 16a have a planar surface, which can be formed by the deposition process or through additional processing such as, for example, CMP.

FIG. 4 shows a patterned backside metal and methods of manufacture in accordance with additional aspects of the present invention. In this embodiment, the backside metal 16 is provided in selected locations over the TSVs 12. That is, the backside metal 16 does not entirely cover the dies 10. Instead, the backside metal 16 covers selected locations over the TSVs 12 and adjacent vicinities. Also, unlike that shown in FIG. 3, the backside of the die 10 is devoid of any metal pads. The backside metal 16 can be formed using a shadow mask, liftoff process or subtractive etch as described above. In any of the deposition processes, the backside metal 16 has a planar surface, which can be formed by the deposition process or through additional processing such as, for example, CMP.

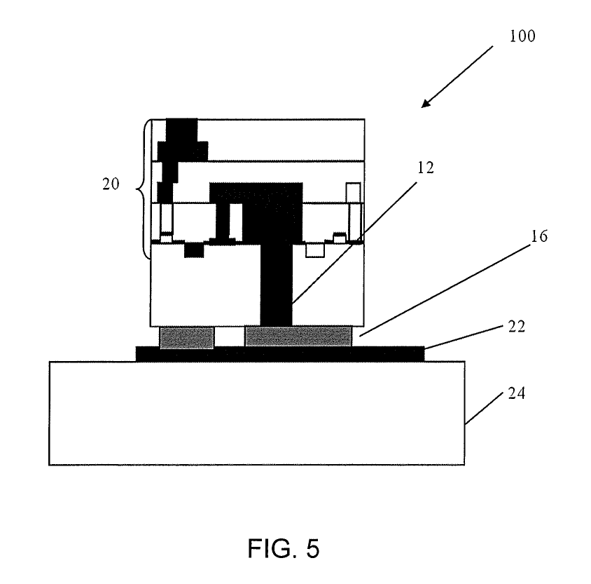

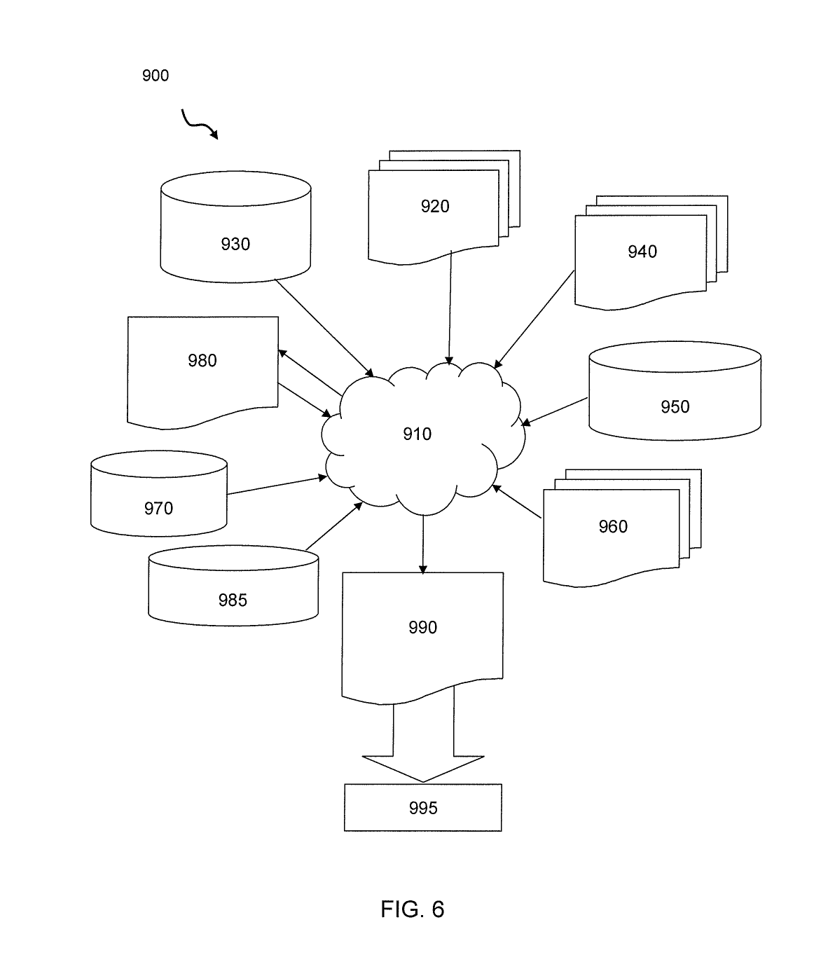

FIG. 5 shows a packaged module with a backside metal ground plane attached to a substrate in accordance with aspects of the present invention. More specifically, FIG. 5 shows a device 100, comprising a plurality of metal wiring layers 20, one of which is at least in electrical communication with the TSV 12. The wiring layers 20 can include vias, wires, and a host of different active or passive devices, any combination of which is contemplated by the present invention. The TSV 12 is, in turn, in mechanical and electrical communication with the backside metal 16. In embodiments, the backside metal 16 has a planar surface, which connects to a substrate ground plane 22. The substrate ground plane 22 is bonded to the substrate 24. In embodiments, the construction of the device 100 does not require wirebonding techniques.

FIG. 6 is a flow diagram of a design process used in semiconductor design, manufacture, and/or test. FIG. 6 shows a block diagram of an exemplary design flow 900 used for example, in semiconductor IC logic design, simulation, test, layout, and manufacture. Design flow 900 includes processes, machines and/or mechanisms for processing design structures or devices to generate logically or otherwise functionally equivalent representations of the design structures and/or devices described above and shown in FIGS. 1-5. The design structures processed and/or generated by design flow 900 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 900 may vary depending on the type of representation being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA) offered by Altera® Inc. or Xilinx® Inc.

FIG. 7 illustrates multiple such design structures including an input design structure 920 that is preferably processed by a design process 910. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission, gate array, or storage medium, design structure 920 may be accessed and processed by one or more hardware and/or software modules within design process 910 to simulate or otherwise functionally represent an electronic component, circuit, electronic or logic module, apparatus, device, or system such as those shown in FIGS. 1-5. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown in FIGS. 1-5 to generate a netlist 980 which may contain design structures such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is resynthesized one or more times depending on design specifications and parameters for the device. As with other design structure types described herein, netlist 980 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 970, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 910 may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990.

Design structure 990 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-5. In one embodiment, design structure 990 may comprise a compiled, executable HDL simulation model that functionally simulates the devices shown in FIGS. 1-5.

Design structure 990 may also employ a data format used for the exchange of layout data of integrated circuits and/or symbolic data format (e.g. information stored in a GDSII (GDS2), GL1, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-5. Design structure 990 may then proceed to a stage 995 where, for example, design structure 990: proceeds to tape-out, is released to manufacturing, is released to a mask house, is sent to another design house, is sent back to the customer, etc.

The method as described above is used in the fabrication of integrated circuit chips. The resulting integrated circuit chips can be distributed by the fabricator in raw substrate 5 form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
forming at least one die adjacent to at least one other die on a substrate, wherein:
the at least one die and the at least one other die are separate functional circuits separated by a dicing channel, and
the at least one die comprises through silicon vias (TSVs);
selectively forming a metalized ground plane within separate areas on a backside of the substrate, wherein:
the separate areas on the backside of the substrate are outside the dicing channel,
the metalized ground plane contacts the TSVs, and
the metalized ground plane does not interfere with dicing operations performed within the dicing channel.

2. The method of claim 1, wherein the forming of the metalized ground plane eliminates peeling when the substrate is diced.

3. The method of claim 1, wherein the forming the metalized ground plane comprises depositing a metal on a backside of each die only to form separate islands, in contact with the TSVs.

4-5. (canceled)

6. The method of claim 1, wherein the forming of the metalized ground plane is formed by a shadow mask process.

7. The method of claim 1, wherein the forming the metalized ground plane is formed by a liftoff process.

8. The method of claim 1, wherein the forming the metalized ground plane is formed by a subtractive etch process.

9. The method of claim 1, wherein the forming the metalized ground plane comprises forming dummy metal pads on a backside of the die.

10. (canceled)

11. A method comprising:
forming a plurality of dies on a substrate, wherein:
the plurality of dies comprise separate functional circuits separated by dicing channels, and
the plurality of dies each comprises a plurality of through silicon vias (TSVs);
depositing a metal within selected areas on a backside of the substrate, wherein:
the selected areas on the backside of the substrate are outside the dicing channels; and
the metal is patterned to contact the TSVs on the plurality of dies; and
dicing the substrate within the dicing channels to separate the plurality of dies, wherein the dicing avoids contact with the metal on the selected areas on the backside of the substrate.

12. The method of claim 11, wherein the depositing of the metal eliminates peeling when the substrate is diced.

13-14. (canceled)

15. The method of claim 11, wherein the depositing of the metal is formed by a shadow mask process.

16. The method of claim 11, wherein the depositing of the metal is formed by a liftoff process.

17. The method of claim 11, wherein the depositing of the metal is formed by a subtractive etch process.

18. The method of claim 11, wherein the depositing of the metal comprises forming dummy metal pads on a backside of the die.

19. The method of claim 11, wherein the depositing of the metal does not completely cover the backside of the die.

20. A structure, comprising:
a substrate comprising a plurality of dies, wherein:
the plurality of dies are separate functional circuits, and
the plurality of dies each comprise a plurality of through silicon vias;
dicing channels provided between the plurality of dies; and
a metalized ground plane within separate areas on a backside of the plurality of the dies in contact with the silicon vias,
wherein:
the separate areas are islands of metal at locations outside the dicing channels such that the dicing channels are substantially devoid of the metalized ground plane, and
the locations correspond to respective locations of the plurality of dies.

21. The method of claim 1, wherein:
the forming of the metalized ground plane comprises forming the metalized ground plane using a shadow mask process;
the forming of the metalized ground plane eliminates peeling when the substrate is diced;
the separate areas are islands of metal at locations on the backside of the substrate that correspond to respective locations of the at least one die and the at least one other die on the substrate;
the islands of metal contact the TSVs; and
the method further comprises:
forming dummy metal pads on a backside of the at least one die; and
dicing the at least one die and the at least one other die by cutting the substrate within the dicing channel.

22. The method of claim 11, wherein:
the depositing the metal comprises forming a metalized ground plane using a shadow mask process;
the forming of the metalized ground plane eliminates peeling when the substrate is diced;
the selected areas are islands of the metal at locations on the backside of the substrate corresponding, respectively, to locations of the plurality of dies on the substrate;
the islands of metal contact the TSVs; and
the method further comprises forming dummy metal pads on backsides of the plurality of dies.
